(19) United States
(12) Patent Application Publication
(10) Pub. No.: US 2007/0033471 A1
(43) Pub. Date: Feb. 8, 2007

(54) Hardware Configuration of pBIST

(76) Inventors: Raguram Damodaran, Plano, TX (US); Ananthakrishnan Ramamurti, Irvine, CA (US); Umang B. Thakkur, Dallas, TX (US)

Correspondence Address: TEXAS INSTRUMENTS INCORPORATED, P O BOX 655474, M/S 3999, DALLAS, TX, 75265, US

(21) Appl. No.: 11/422,743

(22) Filed: Jun. 7, 2006

Related U.S. Application Data
(60) Provisional application No. 60/688,958, filed on Jun. 9, 2005.

(51) Int. Cl. G01R 31/28

(52) U.S. Cl. 714/733

(57) ABSTRACT

This invention is a method of constructing an integrated circuit with built-in self test. The built-in self test includes a built-in self test unit a read only memory storing test algorithms and test data. The built-in self test unit of a particular integrated circuit includes a subset of all test circuits for inclusion for testing a universe of possible operational circuits. The selected subset corresponds to operational circuits of the current integrated circuit.

### CLAIM OF PRIORITY

This application claims priority under 35 U.S.C. 119(e)(1) to U.S. Provisional Application No. 60/688,978 filed Jun. 9, 2005.

### TECHNICAL FIELD OF THE INVENTION

The technical field of this invention is programmable integrated circuit built in self test.

### BACKGROUND OF THE INVENTION

Testing fabricated integrated circuits to determine proper operation has always been a difficult problem. There are two major types of errors. A design defect means that the integrated circuit was manufactured to a design not proper for the intended purpose. Such a defect will effect every integrated circuit until the design is changed. The integrated circuit manufacturer must detect and correct such defects before shipping large number of parts to customers to avoid a costly recall. A manufacturing defect involves some fault in the manufacture of the integrated circuit that will effect less than all parts manufactured. Such defects are corrected by identification and correction of the manufacturing fault.

Most integrated circuit manufacturers test integrated circuits for proper function before shipment to customers. With the increase in integrated circuit complexity this testing is increasingly difficult. Many manufacturers rather than rely on increasingly expensive external testing devices test integrated circuits using a technique called built-in self test (BIST). BIST involves using circuits manufactured on the integrated circuit to test the integrated circuit. When triggered either automatically in circuit operation of by an external test device, the BIST circuits produce a set of test conditions run on the ordinary circuit hardware. Comparison of the state of the integrated circuit following test to an expected state indicates whether the integrated circuit passed the test. An example of such a test is writing to a read/write memory and recalling the data written. A match between the data written and the data read results in passing the test. BIST typically involves other more complex tests.

A subset of BIST is programmable built-in self test (pBIST) uses a general purpose test engine programmed by a set of instructions. This set of test instructions is typically stored on the integrated circuit in a read only memory (ROM) storing test instructions particularly developed for that integrated circuit. pBIST enables re-use of hardware and test instructions to cover a family of similar but not identical integrated circuits. pBIST typically does not have the ability to support go/no-go type of testing using an instruction ROM.

The pBIST unit of current use are a superset of all the features which an integrated circuit design team may not want during various stages of its product development. These design teams are currently forced to use pBIST unit in its entirety which results in bigger area

### SUMMARY OF THE INVENTION

This invention is a method of constructing an integrated circuit with built-in self test. The built-in self test includes a built-in self test unit a read only memory storing test algorithms and test data. The built-in self test unit of a particular integrated circuit includes a subset of all test circuits for inclusion for testing a universe of possible operational circuits. The selected subset corresponds to operational circuits of the current integrated circuit.

Various hardware configuration options that would drop all of the corresponding logic when not needed. There are also other options to reduce test time. These several configuration options permit integrate circuit designers select a compromise between area, test time and available functionality.

### BRIEF DESCRIPTION OF THE DRAWINGS

These and other aspects of this invention are illustrated in the drawings, in which:

FIG. 1 is a block diagram of a typical integrated circuit including a programmable built-in self test unit (prior art);

FIG. 2 is a block diagram of the programmable built-in self test unit of this invention;

FIG. 3 is a block diagram of the address generation unit of the programmable built-in self test unit of FIG. 2;

FIG. 4 illustrates an example of the coding of the programmable built-in self test read only memory illustrated in FIG. 1 according to this invention;

FIG. 5 illustrates an example of the algorithm section of the programmable built-in self test read only memory illustrated in FIG. 4 according to this invention;

FIG. 6 illustrates an example of the memory group section of the programmable built-in self test read only memory illustrated in FIG. 4 according to this invention; and

FIG. 7 illustrates the hardware options available according to this invention.

### DETAILED DESCRIPTION OF PREFERRED EMBODIMENTS

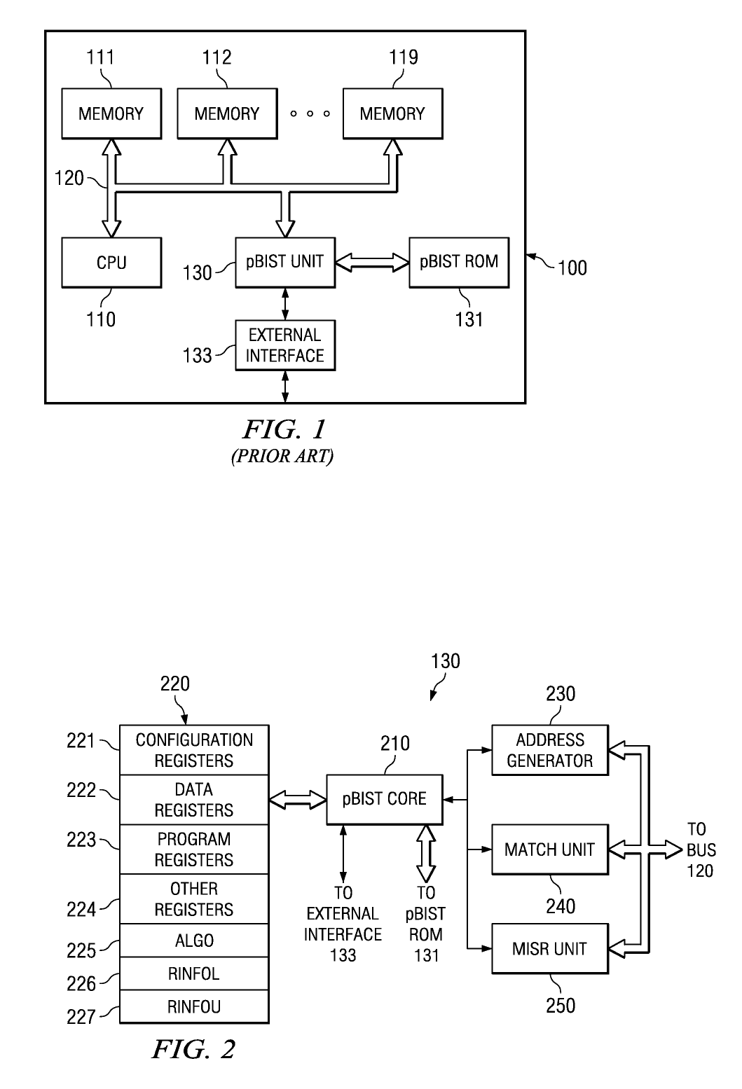

FIG. 1 illustrates a typical integrated circuit 100 including programmable built-in self test. FIG. 1 illustrates integrated circuit 100 including central processing unit (CPU) 110 and memories 111, 112 . . . 119 coupled by bus 120. These circuits are merely representative of circuits embodied in an integrated circuit including pBIST.

The programmable built-in self test includes pBIST unit 130, pBIST ROM 131 and external interface 133. pBIST unit 130 controls the tests in much the same fashion as CPU 110 controls operation of integrated circuit 100. pBIST unit 130 is controlled by test instructions stored in pBIST ROM 131. pBIST unit 130 may couple to circuits outside integrated circuit 100 via external interface 133. FIG. 1 illustrates pBIST unit 130 coupled to CPU 110 and memories 111, 112 . . . 119 via bus 120. This connection is merely illustrative of the type of connection between pBIST unit 130 and other circuits of integrated circuit 100.

FIG. 2 illustrates a more detailed view of pBIST unit 130. pBIST unit 130 includes pBIST core 210, registers 220, address generator 230, match unit 240 and MISR unit 250. pBIST core 210 is the center of pBIST unit 130. pBIST core 210 is coupled to registers 220, pBIST ROM 131, external interface 133, address generator 230, match unit 240 and MISR unit 250. Interaction of pBIST core 210 with these circuits will be further described below.

Registers 220 are preferrably memory mapped within the address space of CPU 110. Thus CPU 110 can read from or write to any register within registers 220 by a memory operation to a corresponding address. Registers 220 include configuration registers 221. Configuration registers 220 control the configuration of pBIST unit 130 and the operational mode of pBIST unit 130. Data registers 222 store test data recalled from pBIST ROM 131 in a manner more fully described below. Program registers 223 store test program instructions recalled from pBIST ROM 131 in a manner more fully described below. Other registers 224 include miscelanous registers not fully described. Registers 220 includes three registers described in detail below: ALGO register 225; RINFOL register 226; and RINFOU 227.

The ALGO register 225 is an algorithm mask register. Bit [0] of this register indicates whether the first algorithm stored in the ROM would be executed or not. Bit [1] indicates whether the second algorithm is executed and so on. A total of 32 algorithms can be stored in the ROM as is determined by the data width of ALGO register 225. For an algorithm to be executed, both the corresponding bit of the ALGO register and a valid bit in the previous algorithm header must be set. The details of this valid bit will be further described below.

The RAM group mask registers RINFOL register 226 and RINFOU register 227 are similar to ALGO register 225. RAM group mask registers RINFOL register 226 and RINFOU register 227 indicate whether a particular RAM group is executed or not. This capability is provided because not all algorithms can be run on all memories. For a particular RAM group to be executed, the corresponding bit in RINFOL register 226 or RINFOU register 227 and the valid bit in the previous RAM group header must both be set. RINFOL register 226 indicates the validity of RAM groups 0 to 31 and RINFOU register 227 indicates the validity of RAM groups 32 to 63. These RAM groups will be further described below.

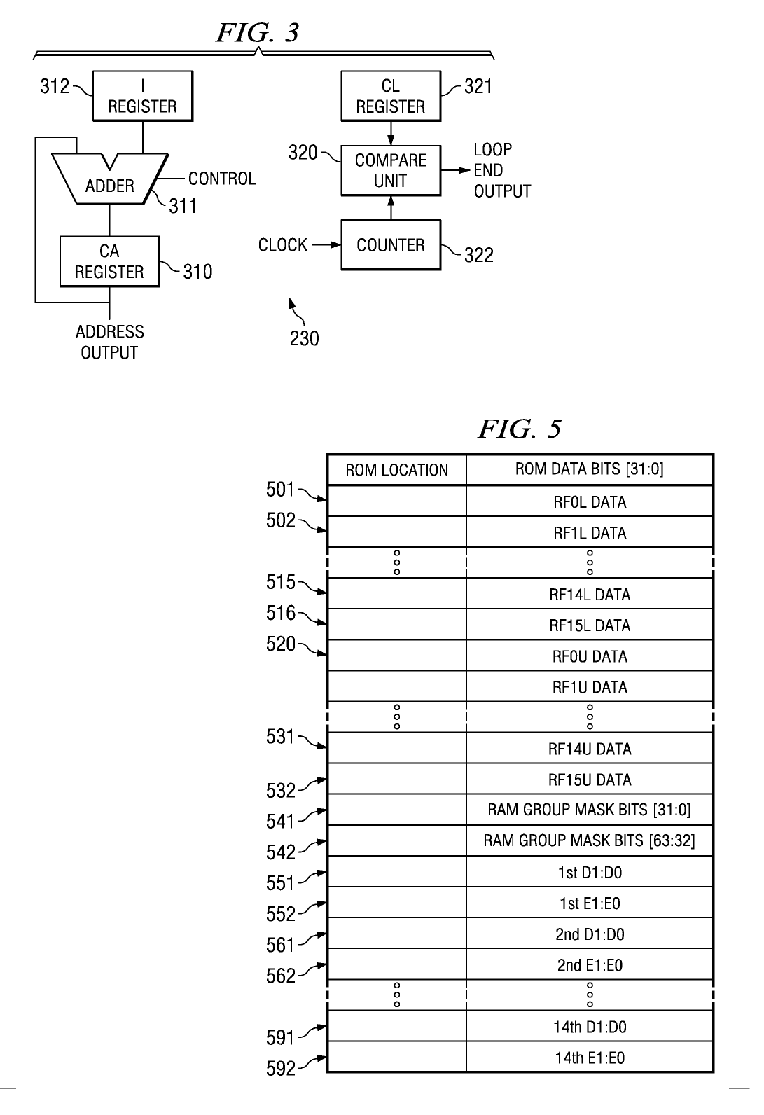

Address generator 230 preferrable includes two address generators used in accessing memory, such as memories 111, 112 . . . 119. FIG. 3 illustrates a block diagram of one of these address generators. Address generator 230 includes CA address register 310, adder 311, I increment register 312, compare unit 320, loop count register 321 and counter 322. In the preferred embodiment the initial values of address register CA 310, increment register I 312 and loop count register 321 are recalled from pBIST ROM 131. Adder 311 is controlled via a control input in one of three modes. In a non-increment mode, adder 311 returns an address output equal to the recycled value of CA register 310. The value of CA register 310 is thus unchanged. In an increment mode, adder 311 adds the values stored in CA register 310 and I increment register 312. The sum value is stored in CA address register 310 for the next iteration. The decement mode is similar to the increment mode, except adder 311 subtracts the value of I increment register 312 from the value of CA address register 310. The difference value is stored in CA address register 310 for the next iteration. The initial value of CL loop count register 321 sets the number of iterations in the loop. Compare unit 320 compares the value of CL loop count register 321 with the value of counter 322. Upon starting a test counter 322 is reset to zero. The count of counter 322 advances by one each cycle of the clock input. Compare unit 320 generates a loop end output when these two values match.

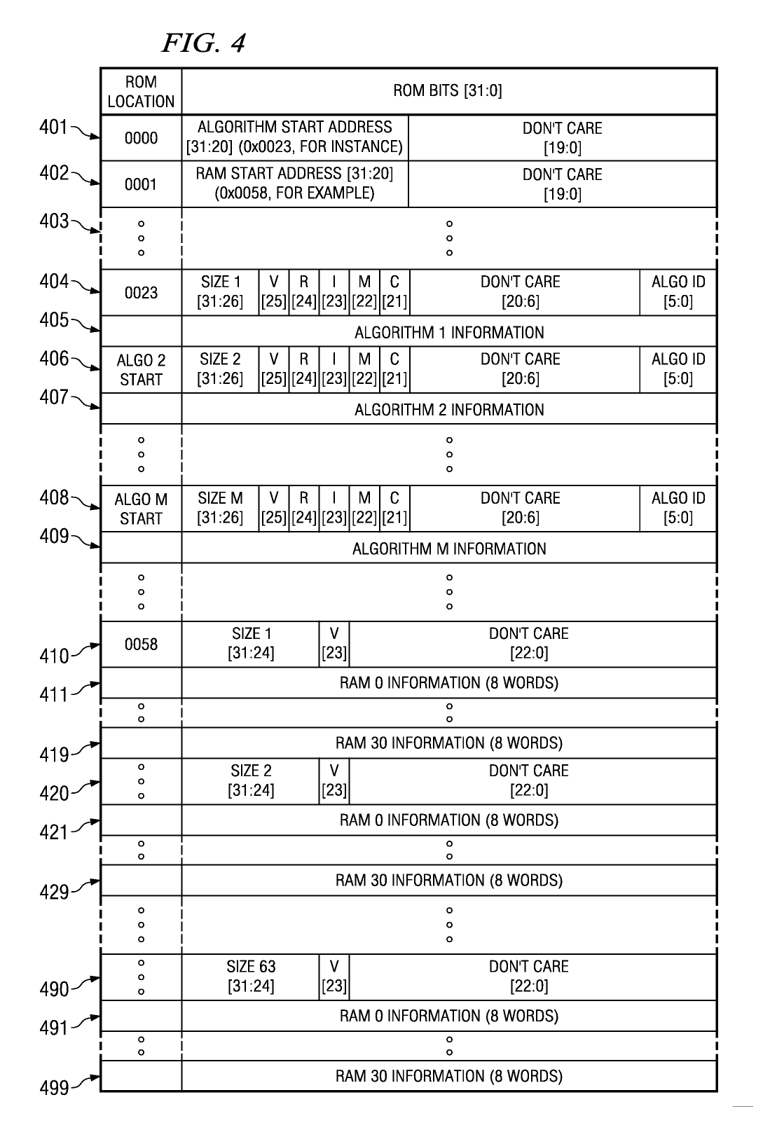

FIG. 4 illustrates an example of the data stored in pBIST ROM 131 according to this invention. This new organization supports a ROM interface and ROM access protocol that simplifies memory testing directly from pBIST ROM 131. pBIST ROM 131 is divided into two regions. The first region stores algorithms and the second region stored data or memory information. ROM-based testing flow stems from pre-loading all the necessary algorithms and memory information on a ROM. All the programmer needs to do is set pBIST unit 130 in ROM mode and pBIST unit 130 takes care of the rest. pBIST unit 130 internally downloads the algorithms from pBIST ROM 131 one after the other. For every algorithm that gets downloaded, pBIST unit 130 also downloads the memory information stored in pBIST ROM 131 and runs the test on corresponding memories, such as memories 111, 112 . . . 119. pBIST unit 130 preferrably also has the capability to selectively run the algorithm only on specific RAM groups by setting a RAM group mask, downloading only the algorithm portion of the ROM, or only the memory information from the ROM. This will be described more fully below.

ROM-based testing by pBIST 130 are preferrably enabled in two ways. First, a single bit signal on external interface 133 could simply be asserted. This signal would come from an external test device not shown in FIG. 1. This initiates ROM-based testing. Testing proceeds automatically until all the algorithms get executed on all the memories. This signal is deasserted to take pBIST unit 130 out of ROM mode.

Second, an internal configuration register which is part of configuration registers 220 includes a bit to start testing. In this option, writing ‘1’ to a particular bit of this internal configuration register initiates ROM-based testing. This option can be used either when there is no access to the external signal of the first method, or when the particular application dictates the ROM-based testing be started using a different interface. Writing a ‘0’ to this bit of the configuration register takes pBIST unit 130 out of ROM mode.

A two-bit memory-mapped ROM configuration register pbist_rom[1:0] part of configuration registers 221 determines what gets executed from pBIST ROM 131. pbist_rom[1] acts as an enable for the algorithm section of the ROM and pbist_rom[0] for the RAM data section. The default state following reset is “11.” This state causes both the algorithm and memory information will be downloaded from pBIST ROM 131. Table 1 lists the various modes enabled by this register.

TABLE 1

| State | Mode |
|---|---|
| 11 | Both algorithm and memory data are used |
| 00 | Nothing from the ROM gets used |
| 10 | Only the algorithm is used |
| 01 | Only memory data is used |

In the “10” mode, the programmer needs to set all the internal pBIST configuration registers and the memory information before enabling the ROM mode using one of the two methods described above. This mode executes each algorithm in the ROM for this corresponding memory information. In the “01” mode, the programmer needs to load the algorithm into the internal register files through an available interface. pBIST core 210 loads the memory data from pBIST ROM 131 into data registers 222 and/or loads the algorithm data from pBIST ROM 131 into program registers 223 on starting in the ROM mode.

FIG. 4 illustrates an example of how pBIST ROM 131 contents are organized. pBIST ROM 131 can hold both algorithm information and memory information. The test developer can choose to load both types of information or just one of the two by setting the appropriate bits in the memory-mapped ALGO register 225, RINFOL register 226 and RINFOU 227.

As illustrated in FIG. 4, the first two words 401 and 402 are addresses. First word 401 holds the start address for the first algorithm header 404. Second word 402 hold the stare address of the first RAM group header 410. In this example first word 401 holds the address hex 0023. Following an optional gap 403 is the algorithm section. As specified in first word 401 the algorithm section begins at address hex 0023. The respective algorithm sections include a header 404, 406 and 408 and algorithm information 405, 407 and 409. Each header 404, 406 and 408 specifies: the algorithm section size in size bits [31:26]; validity of the following algorithm in valid bit [25]; retention mode in retention bit [24]; IDDQ mode in I bit [23]; and MISR mode in MISR bit [22].

Each algorithm header valid bit that specifies the validity of the algorithm following the current one and not that of the current algorithm itself. The first algorithm is always executed provided the corresponding pbist_rom mask bit is set. In short, the valid bit marks the last algorithm. A value of ‘0’ in the algorithm header valid bit denotes the current algorithm is the last.

There cannot be any gaps within the algorithm section. What this means is that the address location has to be continuous from the first line of the first algorithm to the last line of the last algorithm. Likewise, there cannot be any gaps within the RAM groups. It has to be continuous all the way from the first RAM group to the sixty-third RAM group. However, there could be an address gap between the algorithm section and the RAM group section and between the first 2 words and the beginning of the algorithm section.

In addition to the size and valid bits, the algorithm header 404, 406 and 408 has four bits that specify a corresponding memory testing mode. When the retention bit [24] is set, pBIST unit 103 asserts a retention signal output by external interface 133 going out. pBIST unit 130 waits to revieve a pbist_resume signal before it continues on the next algorithm.

If the IDDQ bit [23] is set, then pBIST unit 130 is set in IDDQ mode. In this mode, the instruction WRITE_IDDQ can be used to write inverted data back to the memories.

MISR bit [22] should be set mainly for testing other chip-level ROMs. However, it can also be used to test any memory using any algorithm. If this bit is set, then the return data from the memories is not compared to expected data and no failures would be triggered. The read data is fed directly into a MISR instead. The following polynomial is used by the MISR logic:
x³+x²+x+x+1.
The tap points are bits 31, 30 and 10. The default value at the MISR output after reset is:
hex AAAAAAAA.
At the end of the memory test, the MISR signature is compared with the expected signature in the data register D1:D0 within other registers 224 to determine whether the test is passed or failed.

Bit [21] of the algorithm header specifies the Cumulative MISR mode. This mode is different from the MISR mode in two ways. First, the MISR signature comparison with the expected signature is done after testing all the memories in a particular RAM group and not after each individual memory. Second, this mode gives the programmer the capability to initially load a background pattern in data registers D1:D0 and E1:E0 within other registers 224 for the memory testing. After the memory testing is over, this mode loads a new value into these registers in order to use as expected signature. In other words, the first D1:D0 and E1:E0 values serve as the background pattern and the second D1:D0 and E1:E0 values serve as the expected signature. Any additional values for D1:D0 and E1:E0 will be ignored. Thus in CMISR mode, only the first two pairs of D1:D0 and E1:E0 values are used.

The last 6 bits of each algorithm header bits [5:0] have a unique algorithm ID. This will help in debugging efforts to find out which algorithm caused a memory failure. The test developer can choose not to use these fields. However, these 6 bits of algorithm ID will always get scanned out as part of failure data.

There are 12 bits for the ROM address. So the maximum possible size is 4K words. How these 4K words are partitioned between the algorithms and the RAM groups is up to the test developer. Other embodiments may have greated than this address bus width to 16 bits in order to support chips with larger memories.

FIG. 5 illustrates an example of the coding of an alogrithm section 405, 407 and 409. The first 32 words 501 to 532 of each algorithm section are test instructions that will be loaded into program registers 223 in pBIST unit 130. The next two words 541 and 542 set the mask for RAM groups. This is needed because not all algorithms can be run on all RAM groups. The test developer is responsible for grouping memories according to their type, etc. There could be up to 64 different RAM Info groups,and each having a maximum of 31 memories. This mask value is loaded onto an internal 64-bit register in other registers 224 in pBIST unit 130 that determines at run time which RAM groups the algorithm would get executed upon. From the preceding information, it can easily be seen that each algorithm section is at least 34 words long.

Following the algorithm and mask portions, starting at word 551 are the actual data values the algorithm needs to use. These are the background patterns for the corresponding algorithm. Data values are always downloaded in pairs into data registers 222. The first access being for 32-bit register D1:D0 and the second access for data register E1:E0. Since there might be a need to test the memories using the same algorithm for more than one background pattern, multiple data values for the same algorithm are supported. So for every pair of data that gets downloaded from pBIST ROM 131, the ROM interface logic would sweep, one at a time, all the 64 RAM groups or the total number of RAM groups actually present. After all the memories are tested with this data, the next available data pair is downloaded from pBIST ROM 131 and the RAM group sweep repeats. Once all the data values for a particular algorithm are used, the ROM controller would move onto the next algorithm. This continues until all the algorithms get executed for all the possible RAM groups.

Each algorithm's header 404, 406 and 408 carries the 6-bit size information for that particular algorithm. Thus size of an algorithm with its corresponding data can be a maximum of 2⁶−1=63 words long. Since the algorithm and the mask information take up the first 34 words, each algorithm can support up to 14 different data values for D1:D0 and E1:E0 for a total of 62 words. The 63^{rd} word is not used since D1:D0 and E1:E0 are always downloaded as a pair.

After the algorithm section is the RAM group section. As noted in second word 402 the first RAM group section begins at hex 0058. Each RAM group has its own header 410, 420 and 490 specifying its size in size bits [31:24], and validity of the next RAM group in valid bit [23]. Under each RAM group is the information relating to different RAMs within that group at data words 411 to 419, 421 to 429 and 491 to 499.

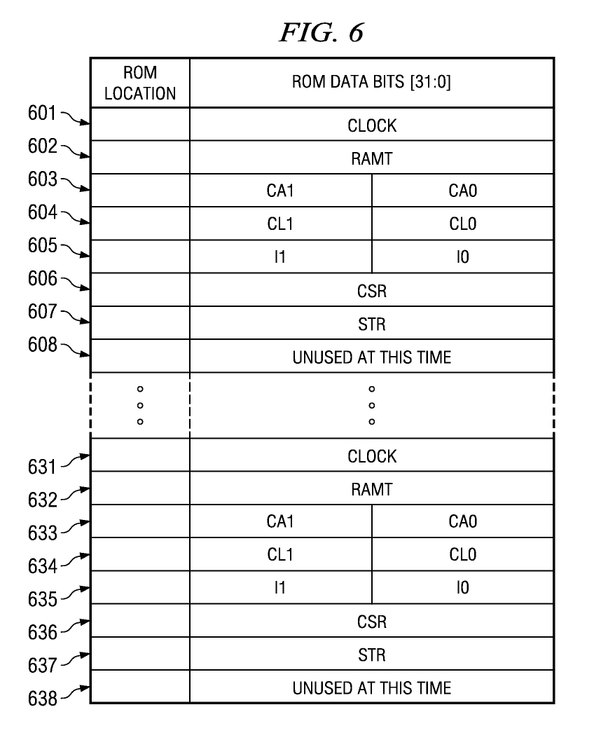

FIG. 6 illustrates an example of the coding of a RAM group. A total of 64 RAM groups are supported. Each RAM group can hold information for up to 31 different memories. Each memory information 411 to 419, 421 to 429 and 491 to 499 is eight words. Word 601 specified clock it uses (Clock). Word 602 specifies an ID, data width and latency as part of RAMT. Word 603 specifies initialization values for the address registers CA1 and CA0 (311 in FIG. 3). Word 604 specifies initializations values for loop count registers CL1 and CL0 (321 in FIG. 5). Word 605 specifies initialization values for increment registers I1 and I0 (312 in FIG. 3). Word 605 (CSR) can enable multiple memories within a particular group can be activated at the same time. This may be useful for IDDQ leakage tests. Multiple memories would be activated but return data would be read from only one memory. Word 607 (STR) is always loaded with the value 0x1 to indicate the memory test is ready to be started. Word 608 is not used at this time. FIG. 6 illustratew word 631 to 638 for another RAM group.

Since a total of 31 different memories are supported for each RAM group, the total size of a RAM group can be a maximum of 31×8=248 words. This is denoted by the 8-bit size field [31:24] in each RAM group header. The 8-bit value indicates that only a maximum of 2⁸−1=255 words can be stored in a RAM group. Since having 32 memories in a RAM group would require 256 words, only a maximum of 31 memories per RAM group is supported.

A go/no-go mode of testing is the default mode for pBIST unit 130. This enables a direct push-button type of testing using the pBIST ROM 131. In this mode, execution stops on the first failure and both FAIL and DONE signals are asserted as outputs on external interface 133. The test does not proceed after the first failure as the main purpose of this mode is to determine just pass/fail. After detecting a failure, the test user can access pBIST unit 130 through external interface 133 or by memory mapped access to data registers 220 to get more information about the failure. However, if data logging is desired while in go/no-go mode, then a datalog-enable signal could be asserted via external interface 133 to enable logging out of failure data. In this case, execution would not stop after the first failure and would continue until all the algorithms have been executed on all the memories.

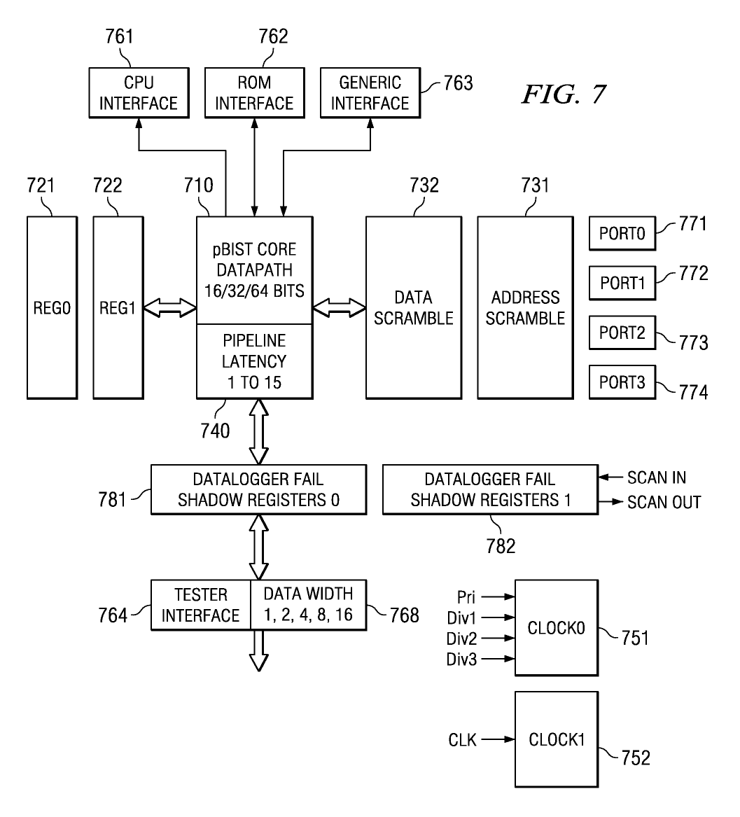

FIG. 7 illustrates the hardware options available in the preferred embodiment of this invention. The integrated circuit design team now have complete control over what features they want to include in pBIST unit 130. This gives the design team the flexibility to arrive at an advantageous compromise between area, test time and functionality. The list below outlines the major options available in this invention.

1) Synthesize Register Files:

If this option is set to ‘0’, the register files are instantiated from an available designware library as Reg0 721. This would result in significant area savings. If this option is set to ‘1’, then the internal register files are instead synthesized as regular flip-flops as Reg1 722. Synthesized flip-flops help in improved ATPG/DBIST based coverage.

2) Datapath Width:

pBIST 130 by default has a 32-bit wide datapath. However, this width is completely configurable as 16-bit, 32-bit or 64-bit wide datapath. FIG. 7 illustrates pBIST core datapath 710 with selectable 16 bit, 32 bit and 64 bit width. A datapath width of 16 bits is useful when only a few small memories are present. In this case, a higher width might turn out to be an overkill. A datapath width of 64 bits would increase the area but at the same time would result in significant reduction in test time as memories up to 128 bits wide could now be tested at the same time.

3) Enable Address/Data Scrambling:

Address and data scrambling is completely configurable. Optional address scrambler 731 enables an arbitrary mapping of input address lines to output address lines. Similarly, optional data scrambler 732 enables an arbitrary mapping of input data lines to output data lines. These features are useful when address or data bits have been swiggled post silicon. However, if these features are not required, their omission could result in significant area savings.

4) Pipeline Latency:

A 4-bit configurable option 740 is used to indicate a latency between 1 and 15. This option is very useful if for instance the maximum latency through out a chip is only 4. Lowering the value set for this option could result in considerable area savings since a smaller amount of data needs to be tracked during memory reads. This option directly affects the depth of the register files in the datalogger.

5) Clock Divider:

pBIST unit 130 expects four clocks at its inputs in addition to an external asynchronous clock. These four clocks are a primary clock, div2, div3 and div4 are supplied to clock0 751. However, the integrated circuit design team which does not have all these clocks available could decide to use an internal clock divider by setting this option. In this case, only a primary clock input is needed. All other clocks used in pBIST unit 130 are locally derived from this primary clock by clock 1 752.

6) Available Interfaces:

pBIST unit 130 by default supports four interfaces. These are a CPU interface 761, a ROM interface 752, a generic interface 753 and a tester interface 754. Each of these interfaces could be individually configured to be used or not. If a particular interface is not used, then all the corresponding signals going from this interface to the controller will automatically be tied low. In addition, the corresponding logic from this unused interface would be omitted during circuit synthesis resulting in significant area savings.

7) VLCT Programmation Port Width:

By default, a 16-bit very low cost tester (VLCT) programmation bus 768 is assumed. However, a lower width bus could be used in cases where 16 pins are not available at the chip level for this purpose. Selectable widths of 1, 2, 4, 8 and 16 are supported in data width bus 768. Please note that the number of available pins should include both the data pins and the control pins. Any value less than 16 would increase the area slightly as the supporting logic now needs to be accounted for. This configurable option would be ignored when the VLCT interface option is not selected.

8) Number of Ports:

The number of ports 771, 772, 773 . . . 774 available for testing is configurable to 1, 2, 3 or 4. Higher number of ports would significantly increase the area but reduce the test time as more memories could now be tested in parallel. Port0 771 will always be present. Port1 772, port2 773 and port3 774 would be added based on the value set for this option. There is an internal combiner interface that would route the failure data from these ports one at a time.

9) Non-Modifiable Data Registers:

When this option is not chosen, the register file would be 32-bits wide and the data registers internal to pBIST unit 130 such as DL:D0 and EL:E0 would be allowed to be modified during a memory test. When this option is set, the register file would only be 4 bits wide resulting in area savings. However, the internal data registers in this case would be rendered non-modifiable during the memory test. This option also results in considerable area reduction. Both reg0 721 and reg1 722 can support this option.

10) Datalogger Fail Shadow Register:

When this option is set, pBIST unit 130 will not stall on the first failure. Instead, this failure would be captured in a shadow register datalogger fail shadow register0 781 and pBIST unit 130 would continue execution. However, the controller would stall on the second failure and would have to restart after this second failure is processed. For this reason, pBIST unit 130 is automatically set in time stamp mode when this option is set. This option would considerably lower the area but would require a restart after every second failure. It would also reduce test time a little when failures are infrequent. However, in cases where there are frequent failures, this option would end up increasing the test time. In this event datalogger fail shadow register9 782 could be used that would stop test on the first failure.

11) Datalogger Failure Scanout Information:

In the prior art the failure scanout was of fixed data width and would include pre-determined fields all of which an integrated circuit design team may not necessarily want. This fixed scannout prevents other potentially useful new data from being added to the scanout information as the total time it would take to scanout all the fields would then go up linearly. Thus this invention makes the failure scanout information completely configurable. Datalogger fail shadow register0 781 and datalogger fail shadow register1 782 have selectable connection of regiter bits to the scan chain. The integrated circuit designers can individually pick only the information that they want scanned out. This would directly reduce the total test time especially if multiple failures need to be scanned out. Table 2 lists the configurable fields are available as part of the failure scanout information.

TABLE 2

| Option | Data Size |
|---|---|
| Port number | 2 bits |
| Algorith ID | 6 bits |
| RAM Information Group ID | 6 bits |
| Background pattern ID | 4 bits |
| Instruction step | 4 bits |
| RGS Value | 8 bits |
| RDS value | 8 bits |
| Failure Address | 16 bits |
| Failure Data | same as datapath width |

What is claimed is:

1. A method of constructing an integrated circuit with built-in self test comprising the steps of:
forming on the integrated circuit a plurality of operational circuits to be tested;
forming on the integrated circuit a test read only memory storing at least one test set consisting of a test algorithm and test data; and
forming on the integrated a programmable built-in self test unit connected to said plurality of operational circuits to be tested and said test read only memory, said programmable built-is self test unit operable to load from said test read only memory operable for each test set stored in said test read only memory of both said test algorithm and said test data, said forming said programmable built-in self test unit including
designing a set of test circuits for inclusion within said programmable built-in self test unit for testing a universe of possible operational circuits,
selecting a subset of said set of test circuits corresponding to operational circuits constructed on a current integrated circuit, and
forming on the integrated circuit only said selected subset of said test circuits.

2. The method of constructing an integrated circuit of claim 1, wherein:
said set of test circuits includes register files instantiated via a design library and register files synthesized as flip-flops; and
said step of selecting a subset of circuits includes selection for at least one register file within said programmable built-in self test one of a register file instantiated via a design library and a register file synthesized as flip-flops.

3. The method of constructing an integrated circuit of claim 1, wherein:
said set of test circuits includes a plurality of datapaths, each datapath having a differing corresponding datapath bit width; and
said step of selecting a subset of circuits includes selection of a single datapath having one of said corresponding datapath bit widths.

4. The method of constructing an integrated circuit of claim 3, wherein:
said set of test circuits includes a datapath having a datapath bit width of 16 bits.

5. The method of constructing an integrated circuit of claim 3, wherein:
said set of test circuits includes a datapath having a datapath bit width of 32 bits.

6. The method of constructing an integrated circuit of claim 3, wherein:
said set of test circuits includes a datapath having a datapath bit width of 64 bits.

7. The method of constructing an integrated circuit of claim 1, wherein:
said set of test circuits includes an address bit scrambling circuit connecting said programmable built-in test unit to one of said operational circuits; and
said step of selecting a subset of circuits includes selection of said address bit scrambling circuit or not selection of said address scrambling circuit.

8. The method of constructing an integrated circuit of claim 1, wherein:
said set of test circuits includes a data bus bit scrambling circuit connecting said programmable built-in test unit to one of said operational circuits; and
said step of selecting a subset of circuits includes selection of said data bus bit scrambling circuit or not selection of said data bus scrambling circuit.

9. The method of constructing an integrated circuit of claim 1, wherein:
said set of test circuits includes a plurality of pipeline latency circuits, each pipeline latency circuit having a differing total delay; and
said step of selecting a subset of circuits includes selection of one of said plurality of pipeline latency circuits.

10. The method of constructing an integrated circuit of claim 1, wherein:
said set of test circuits includes a first clock circuit operable on a plurality of input clock signals and a second clock circuit operable on a single input clock signal; and
said step of selecting a subset of circuits includes selection of one of said first clock circuit and said second clock circuit.

11. The method of constructing an integrated circuit of claim 1, wherein:
said set of test circuits includes a plurality of interface circuits for interface with differing operational circuits; and
said step of selecting a subset of circuits includes selection of at least one interface circuit corresponding to operational circuits constructed on the current integrated circuit.

12. The method of constructing an integrated circuit of claim 11, wherein:
said set of test circuits includes a tester interface connecting said programmable built-in test unit to an external tester.

13. The method of constructing an integrated circuit of claim 11, wherein:
said operational circuits includes a central processing unit; and
said set of test circuits includes a central processing unit interface connecting said programmable built-in test unit to said central processing unit.

14. The method of constructing an integrated circuit of claim 11, wherein:
said operational circuits includes a read only memory; and
said set of test circuits includes a read only memory interface connecting said programmable built-in test unit to said read only memory.

15. The method of constructing an integrated circuit of claim 1, wherein:
said set of test circuits includes a plurality of external interfaces for connecting said programmable built-in self test unit to an external tester, each external interface having a differing data bus width; and
said step of selecting a subset of circuits includes selection of one of said plurality of external interfaces.

16. The method of constructing an integrated circuit of claim 15, wherein:
said set of test circuits includes an external interface having a data bus width of 1 bit.

17. The method of constructing an integrated circuit of claim 15, wherein:
said set of test circuits includes an external interface having a data bus width of 2 bits.

18. The method of constructing an integrated circuit of claim 15, wherein:
said set of test circuits includes an external interface having a data bus width of 4 bits.

19. The method of constructing an integrated circuit of claim 15, wherein:
said set of test circuits includes an external interface having a data bus width of 8 bits.

20. The method of constructing an integrated circuit of claim 15, wherein:
said set of test circuits includes an external interface having a data bus width of 16 bits.

21. The method of constructing an integrated circuit of claim 1, wherein:
said operational circuits include a plurality of memories;
said set of test circuits includes a memory port for connecting said programmable built-in self test unit to a memory; and
said step of selecting a subset of circuits includes selection of a selected number of said memory ports.

22. The method of constructing an integrated circuit of claim 1, wherein:
said set of test circuits includes a modifiable data register and a non-modifiable data register; and
said step of selecting a subset of circuits includes selection of one of said modifiable data register and a non-modifiable data register.

23. The method of constructing an integrated circuit of claim 1, wherein:
said set of test circuits includes a first circuit to stop test upon detection of a failure and a second circuit to store data corresponding to a first failure and stop test upon detection a second failure; and
said step of selecting a subset of circuits includes selection of one of said first circuit and said second circuit.

24. The method of constructing an integrated circuit of claim 1, wherein:
said set of test circuits includes a serial scan interface, a plurality of memories operable to store a plurality of test data, each of said plurality of memories having differing test data scannable via said serial scan interface; and
said step of selecting a subset of circuits includes selection of one of said plurality of memories.
